(19) United States
(12) Patent Application Publication
(10) Pub. No.: US 2026/0028496 A1
(43) Pub. Date: Jan. 29, 2026

(54) Metal Particle-Free Catalytic Precursor Ink for Electroless Plating

(71) Applicant: Elektrum Technologies, Inc., Denton, TX (US)

(72) Inventor: Yieu Chyan, Denton, TX (US)

(73) Assignee: Elektrum Technologies, Inc., Denton, TX (US)

(21) Appl. No.: 19/279,429

(22) Filed: Jul. 24, 2025

Related U.S. Application Data
(60) Provisional application No. 63/674,874, filed on Jul. 24, 2024.

(51) Int. Cl. C09D 11/52; C23C 18/16; C23C 18/40; C23C 18/44; H05K 3/12; H05K 3/24

(52) U.S. Cl. CPC C09D 11/52; C23C 18/1612; C23C 18/40; C23C 18/44; H05K 3/125; H05K 3/1283; H05K 3/24; H05K 2203/072; H05K 2203/1453

(57) ABSTRACT

A method for making electrically conductive patterns using a metal particle-free ink containing a catalyst precursor that subsequently forms catalytic seed nanoparticles in-situ during or after a patterning step. The catalytic pattern is fixed on the target substrate after which catalytic sites are generated by reduction of the precursor to metallic particles. The reductant is selected to minimize particle generation under ambient conditions but the reduction of the catalyst precursors in the ink may be accelerated by an external input such as heat or ultraviolet energy. This catalytic pattern is then metallized with electroless plating to generate a conductive metallic pattern corresponding to the first catalyst pattern.

### CROSS-REFERENCE TO RELATED APPLICATION(S)

This application claims the benefit of U.S. Provisional Application No. 63/674,874, filed Jul. 24, 2024, the disclosure of which is incorporated herein by reference as if set forth in full.

### TECHNICAL FIELD

This disclosure relates generally to forming conductive patterns for electronics, specifically to ink formulations for making patterns suitable for subsequent electroless plating.

### BACKGROUND OF THE INVENTION

The ability to deposit conductive patterns on a wide range of organic and inorganic substrates is essential to the electronics, solar energy, and display industries. Flexible substrates have recently become an area of intense interest because they enable both new form factors such as foldable and rollable electronics as well as reducing manufacturing costs. Currently, indium tin oxide (ITO) is used in applications that require transparent conductive patterns such as touch screens, solar cells, electrochromic devices, light emitting diodes, and liquid crystal displays. These ITO coatings have significant issues including a high price, relatively low conductivity, and brittleness. As an alternative to ITO, fine metal mesh conductive patterns can be substantially transparent with >90% transmission of visible light.

Beyond transparent conducting electrode applications, the ability to deposit conductive patterns on various surfaces is generally useful for all types of electronics and device manufacturing. Advanced heterogenous packaging for microelectronics requires conductors with dimensions and pitch on the order of microns down to sub-micron scale. There is currently not a cost-effective solution that could handle microscale to macroscale patterning.

### BRIEF DESCRIPTION OF THE DRAWINGS

FIG. 1 shows illustrations of cross-sections of patterns made with inks with varying degrees of hydrophilicity according to embodiments of the present disclosure.

FIG. 2 is a flow chart for a method for implementing the usage of metal particle-free precursor inks wherein catalytic particle generation step occurs separately from the ink curing step and preferably close in time to the plating step according to embodiments of the present disclosure.

FIG. 3 is a flow chart for a method of implementing the usage of metal particle-free catalytic precursor inks wherein the ink curing, and metal ion reduction occurs in one step according to embodiments of the present disclosure.

### SUMMARY OF THE INVENTION

The present invention describes a method for making metal particle-free catalytic precursor ink for electroless plating.

A preferred embodiment of the present disclosure is a self-reducing metal particle-free ink containing a reductant and/or initiator carefully selected to minimize reduction of the metal ions during any storage or patterning steps, but which can be subsequently activated in a step close in time to the electroless metal plating step. This embodiment is particularly suitable for precursor inks that generate catalytic particles (such as particles of copper) that are subject to oxidation that may affect the catalytic activity.

Another embodiment is a self-reducing metal particle-free ink composition where the reductant and/or initiator are selected to cure or partially cure the ink and reduce the reducible metal ions or complexes under similar conditions. This allows for a reduction in the number of process steps required and may be most suitable for generating catalytic nanoparticles that are not expected to oxidize in the time period between the patterning and plating steps.

Another embodiment of a metal particle-free ink is comprised of a composition that is first patterned and cured/partially cured followed by external reduction. The metal ions in the cured pattern may be reduced with a reducing agent via immersion or any other method known to one skilled in the art.

### DETAILED DESCRIPTION

Microelectronic devices frequently require conductive patterns with features on the micron scale or smaller. These patterns are frequently generated using techniques such as photolithography, nanoimprint lithography, or various printing methods such as micro-inkjet, screen, gravure, or flexographic printing. Catalytic inks based on nanoparticles may be used to define a pattern that can be subsequently metallized using electroless plating to generate the desired conductive pattern. The resolution of the patterns can be limited by the size of the particles especially as the particle size or the size of particle aggregations approaches the target dimensions of the patterned feature. This becomes problematic as nanoparticles tend to form aggregations resulting in an unstable and increasing distribution of effective particle sizes. This may interfere with both the mechanical operation of the patterning device as well as limit the resolution of the patterns. Aggregation also tends to reduce available catalytic surface area or negatively affect the distribution of the catalytic sites.

The enhanced techniques of the present disclosure can be used to form metallic particles in-situ from reducible catalytic metal ions such as Pd, Ag, or Cu. The resulting metal particles serve as “seed” catalytic sites for subsequent electroless plating of a suitable metal to provide electrically conductive patterns on articles corresponding to the catalytic ink pattern.

One previous method of preparing fine electrically conductive patterns on films and surfaces involved applying ink formulations containing dispersions of metal particles such as silver nanoparticles in U.S. Publication No. 2015/0165755A1 (Jin et al.). An example of useful devices fabricated with this catalytic ink formulation containing metal nanoparticles to generate a conductive pattern includes U.S. Publication No. 2014/007156 (Petcavich), U.S. Pat. No. 9,188,861 (Shukla et al.) and U.S. Pat. No. 9,207,533 (Shukla et al.). Inks containing silver or copper particles can be printed on transparent substrates such as a continuous roll of polyethylene terephthalate film and subsequently metallized with electroless plating to yield an article with a conductive pattern.

Electroless plating, however, requires that sufficient catalytic sites are available near the surface to initiate the plating. While the distribution of these catalytic sites need not be uniform, agglomerations of metal nanoparticles tend to be denser than the other components in an ink formulation and may settle. Due to this, there may be a tendency to obtain structures with an uneven distribution of particles where there are fewer particles near the exposed surface with particles that are aggregated within the interior of the catalyst pattern. Lack of catalytic sites near the surface may result in difficulty initiating plating. Particle agglomeration also reduces the available catalytic surface area, further reducing the effectiveness of the nanoparticles. Additionally, in the case of copper-based nanoparticle catalyst inks, oxidation of the nanoparticles may negatively impact catalytic activity. As such, the lifetime of catalytic patterns based on Cu nanoparticles may be limited requiring that they be electroless plated within a short period of time after the patterns have been deposited on the target substrate.

Metal particle-free catalytic inks based on reducible Pd metal ions such as palladium (II) chloride or most commonly palladium (II) acetate have been long known. One example can be found in U.S. Pat. No. 8,642,117 B2 (Robinson). Palladium acetate is sufficiently soluble in many non-aqueous formulations and readily decomposes to Pd metal particles upon exposure to heat or light. However, the resulting ink formulation is excessively sensitive and often results in particles forming during storage and patterning resulting rapidly changing ink properties over time. As a result, some have instead preferred to form perform the reduction before the patterning and use a suspended Pd colloid trading the drawbacks of having particles for more consistent performance over time and longer shelf life for the ink. Moreover, while much easier to form a reducible but less stable particle-free ink, Pd is much more expensive than less noble metal catalysts.

U.S. Publication No. 2015/0299489 A1 (Walker) describes a silver ink consisting of a silver carboxylate and alkylamine complex which is first printed and then thermally decomposed to directly yield a conductive metal pattern. However, these inks may not be stable at room temperature or ambient light conditions. Additionally, the cost of the silver and the adhesion of the Ag metal deposits to surfaces may be less than desired.

Metal particle-free means that the majority of the metallic catalyst is initially added to the formulation in the form of reducible metal ions rather than metal particles or nanoparticles. These metal ions may be added in the form of an organometallic or metal complex or in the form of metal salts. Particle-free does not refer to the intentional addition of particles other than catalytic metal particles, especially transparent particles with a similar refractive index to the other ink components. In one embodiment, a “particle-free” ink is one that has preferably less than 0.5% particles. In another embodiment, a “particle-free” ink is one that has less than 1% particles. While reduction of ions may occur during storage of the ink formulation, this is undesirable and may limit the useful lifespan of the ink since this can lead to agglomeration and uneven distribution of catalytic sites as well changes to viscosity.

A metal particle-free ink may contain a mixture of monomers, oligomers or polymers, metal elements, metal complexes, organometallics, in a solid or liquid state that may be applied to a substrate surface. In some embodiments, the concentration of the reducible metal ion, organometallics or metal complexes ranges from 0.05 wt. %-25 wt. %, preferably from 0.1 wt. %-5 wt. %. In other embodiments, the percentage of the catalyst may be adjusted as a function of minimum feature size, the density of the features in each pattern, and the overall bath loading. During plating, the activity of an electroless bath can be locally increased by reactions and byproducts of the plating process but if the features have small dimensions or lower density such increase in activity may not occur in a substantial manner. In some embodiments, the metal catalyst is selected based on the desired feature sizes of the pattern to be deposited. A pattern consisting of micron-scale features might use a more active catalyst such as Pd or Ag whereas a pattern consisting of features on a millimeter or larger scale might use Cu as the catalyst.

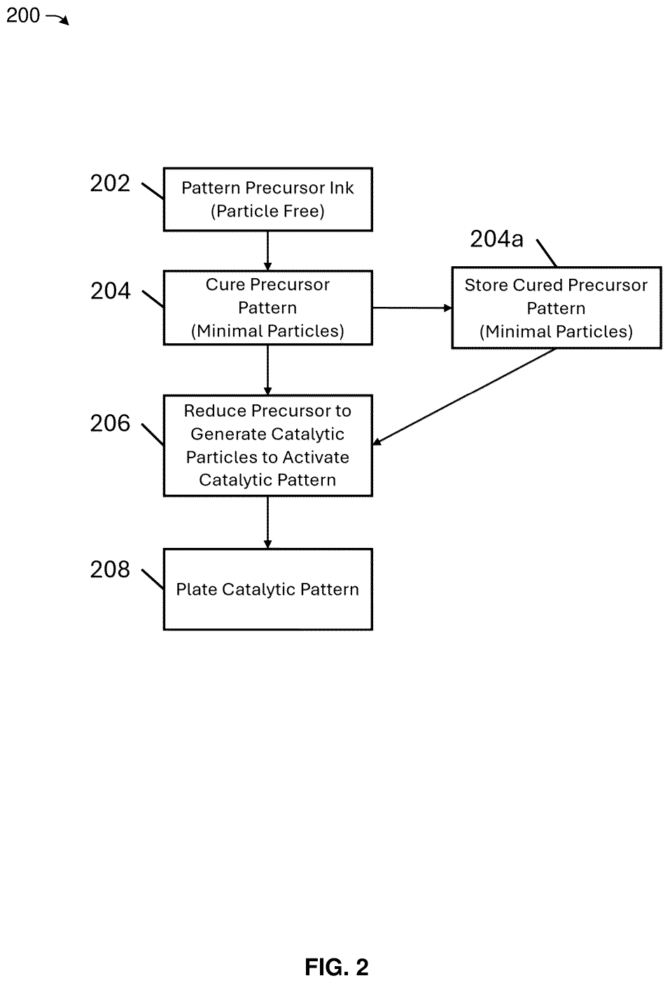

A self-reducing metal nanoparticle catalyst precursor ink comprises at least one monomer, polymer, or oligomer as well as any number of additives. An additive may refer to any ink component that may modify any number of its properties. A self-reducing ink is a composition that contains all the necessary components to form catalytic nanoparticles as patterned. The reduction of the reducible metal ions, reducible organometallics, or metal ion complexes may be initiated by some external activation such as heat or UV energy but does not require the application of a second liquid in a process step after the patterning step. Depending on the metal, the ink formulation may contain a reductant if necessary to reduce metal ions to metal0. More noble metals such as Pd may not require a separate reductant but less noble metals such as Cu may require a separate reductant. An ink additive may be used to increase the permeability of the ink to water to increase the volume of the ink that contacts the aqueous plating solution. One example of such an additive may consist of a hydrophilic polymer. Initiation of metal plating from the interior of the ink may also improve interaction between the plated metal and the patterned ink (FIG. 2).

In some embodiments, the source of the reducible metal ions may be a metal compound such as a salt. Some suitable metals are silver, copper, and nickel. For copper, the metal compound can be a copper (I) compound, a copper (II) compound, or a combination of a Cu (I) and Cu (II) compound. Examples of suitable copper salts include but are not limited to copper sulfate, copper nitrite, copper formate, copper bromide, copper trifluoroacetate, copper acetate, or copper chloride. For silver, metal compounds that are silver (I) compounds are preferred. Example silver salts include but are not limited to silver nitrate, silver perchlorate, silver tetrafluoroborate, silver triflate, silver hexafluorophosphate, silver carbonate, and silver acetate. An appropriate metal compound should be selected based on solubility in the solvents or other components used in the ink. For nickel, useful metal salts may include but are not limited to nickel acetate, nickel formate, nickel chloride, or nickel sulfate. Other suitable salts or compounds of catalytic metals such as gold, nickel, iridium, rhodium, platinum, or palladium may be used.

A compound or functional group suitable for stabilizing the reducible metal ions by forming a metal complex may be used in certain embodiments. For example, ethylenediaminetetraacetic acid (EDTA) and tartaric acid are frequently used as a chelator for Cu in aqueous metal plating solutions. For nickel, exemplary non-nitrogen-based chelators include glycolic acid, malic acid, lactic acid, citric acid, tartric acid succinic acid and their sodium salts. Nitrogen based chelators include but are not limited to triethanolamine, ethylenediamine, aspartic acid, glycine, bipyridyl and EDTA. For copper, exemplary chelating agents include alkyl amines, aldimines, pyrazines, ammonia, amine-aldehyde condensates, alcohol amines, or combinations thereof. Examples of amines suitable for copper chelation include methylamine, ethylamine, triethanolamine, ethylenediamine, and EDTA. For silver, exemplary chelating agents include alkyl amines, aldimines, amine-aldehyde condensates, alcohol amines or combinations there. More specifically, this may include EDTA, diethylenetriamine, triethnolamine, Ethylene glycol-bis-(2-aminoethyl)-N,N,N′,N′-tetraacetic acid (EGTA), nitrilotriacetic acid, and triethanolamine.

For certain metals such as Ag but especially for Cu, the addition of one or more chemical reductants may be required to reduce the reducible metal ions, metal complexes, or organometallics. In some embodiments, this reducing agent may be selected from an alcohol, a polyol, an aldehyde, a dialdehyde, an amide, an imine, an aldimine, an oxime, an aldoxime, a formate, a hydrazine, a hypophosphite, dimethylamine borane or combinations thereof. The selection of the reducing agent should be tailored to the reduction potential of the metal and the strength of the chelator. For example, silver has a standard reduction potential of 0.80V whereas copper has a standard reduction potential of 0.52V. A stronger reducing agent would be required for copper as compared to silver. Another example would be EDTA is a stronger chelating agent than tartrate and would require a stronger reducing agent if all other conditions were kept the same. In some embodiments examples of strong reducing agents may include an alkali metal hydride, a hydride complex of an alkali metal with boron, a hydride complex of an alkali metal with aluminum. Some examples of these include lithium hydride, lithium borohydride, sodium borohydride, and lithium aluminum hydride.

The reductant(s) and chelator(s) may be selected to minimize formation of particles at ambient temperatures. The reduction of the reducible metal ions or metal complexes may be activated by an external input of UV or heat energy. In some embodiments, the composition of the ink is selected such that the UV and or heat in the curing step to at least partially solidify the ink on the substate does not substantially cause reduction generating particles. More intense or more prolonged heat or UV exposure will be required. FIG. 2 is a flow chart illustrating this approach where the ink is first patterned on a surface (202) and then cured without reducing the majority of the ions to particles (204). The precursor pattern then can be optionally stored (204a) until ready to do electroless plating at which time the metal ions or complexes in the precursor pattern are reduced to generate a catalytically active pattern (206). Finally, the pattern is plated (208). This approach is particularly advantageous for metals that are more readily subject to oxidation and loss of activity during the time between when particles are generated, and the pattern plated.

Alternatively, the reductant(s) and chelator(s) and curing conditions may be selected such that the catalytic particles are generated simultaneously with the curing of the polymer components of the ink. This is depicted in the flow chart in FIG. 4. The ink is patterned on the substrate (302). The ink is cured, and the catalytic precursors reduced in the same step (304) followed by metal plating (306). The advantage here is the reduced number of process steps but this may require either a more noble catalyst metal that is less subject to oxidation or that the activated catalytic pattern is plated within a short period of time after it is generated.

A metal particle-free ink is comprised of components that have at least the following functions: (a) monomers, oligomers, or polymers to form a polymeric matrix, (b) reducible metal ions or metal complexes, and (c) a chelator or other compound to stabilize the metal ions in the ink. A self-reducing metal particle-free ink will additionally contain (d) a reductant. Additional additives may be used as thermal initiators, photoinitiators, sensitizers, stabilizers, adhesion promotors, inorganic fillers, or to tune the hydrophilicity of the ink. A solvent may be used to reduce the viscosity of the ink. A single component of an ink may serve one or more functions. For example, in one embodiment, the polymer may have functional groups suitable for both chelating the metal ions as well as reducing them. Alternatively, a reducing compound such as an aldimine, oxime, or aldoxime may also serve to stabilize the metal ions and the resultant metal nanoparticles. Further, a solvent such as glycol or alcohol may serve as the reductant.

A catalytic precursor ink will contain one or more components that are applied to a target surface in a liquid or semi-liquid state but then converted to a polymeric solid or semi-solid state that adheres to the target surface. For example, this could consist of monomers, oligomers, cross-linkable polymers, UV-curable polymers, a thermally curable polymers, or polymers that harden substantially when solvent is evaporated or combinations thereof. A preferred method is to use an acrylic-based UV-curable ink formulation in which a photoinitiator is used to promote polymerization or cross-linking. These resins may include but are not limited to acrylates, acrylamides, styrene acrylic copolymers, epoxy acrylic resins, vinyl acrylic copolymers, polyester acrylates, and hybrid urethane acrylates. The speed of UV-initiated curing via a radical mechanism is advantageous for high volume manufacturing such as by various roll-to-roll printing methods. In other applications, cellulosic polymers, polyurethanes, vinyl polymers, or epoxy resins may be suitable.

In one or more embodiments of the present disclosure, an example formula may be the following:

### Example Formula 1:

Commercial UV-Resin for 3D Printing (50-90%)
2,2′-Ethylenebis(nitrilomethylidene)diphenol (1-3%)
Polyethylene glycol diacrylate (5-10%)
Ethanol (10-50%)
Silver Nitrate (0.05-2%)

2,2′-Ethylenebis(nitrilomethylidene)diphenol was synthesized by a condensation reaction of the aldehyde and amine in MeOH at reflux for 3 hours. The product was recrystallized from MeOH to yield an intensely yellow solid. 2,2′-Ethylenebis(nitrilomethylidene)diphenol and silver nitrate were dissolved in acetonitrile and stirred at room temperature for 4 hours. The adduct was precipitated in cold water and the product was recovered by filtration and recrystallized as necessary to obtain a lustrous pale-yellow solid. This solid was then dissolved in an acrylate-based UV-resin and polyethylene glycol diacrylate and ethanol added. After UV curing and baking, the catalytic patterns thus obtained were plated with electroless chemistry (Enthone Via Dep 4455).

In one or more embodiments of the present disclosure, an example formula may be the following:

### Example Formula 2:

Commercial UV-Resin for 3D Printing (50-90%)
2,2′-Ethylenebis(nitrilomethylidene)diphenol (0.5-1%)
Polyethylene glycol diacrylate (5-10%)
Methanol (10-50%)
Copper Sulfate (0.1-1%)

2,2′-Ethylenebis(nitrilomethylidene)diphenol was synthesized by a condensation reaction of the aldehyde and amine in MeOH at reflux for 3 hours. The product was recrystallized from MeOH to yield an intensely yellow solid. 2,2′-Ethylenebis(nitrilomethylidene)diphenol and copper sulfate were dissolved in MeOH and refluxed for 3 hours. The adduct was precipitated in cold water and the product was recovered by filtration and recrystallized as necessary to obtain a lustrous dark-green solid. This solid was then dissolved in an acrylate-based UV-resin and polyethylene glycol diacrylate and ethanol added. After UV curing and baking, the catalytic patterns thus obtained were plated with electroless chemistry (Enthone Via Dep 4455).

In one or more embodiments of the present disclosure, an example formula may be the following:

### Example Formula 3:

Bisphenol A diacrylate: ˜15 wt. %
Polyethylene glycol diacrylate: ˜15 wt. %
Hydroxyethyl methacrylate: ˜25%
Pentaerythritol tetraacrylate: ˜15%
1-Hydroxy-cyclohexyl-phenyl-ketone: ˜5 wt. %
2,2-Dimethyl-1,2-diphenylethan-l-one: ˜2 wt. %
Silver Nitrate: ˜2 wt. %
Methanol: 20 wt. %

In one or more embodiments of the present disclosure, an example formula may be the following:

### Example Formula 4:

Commercial Low-Temperature Thermally Cured 1 Part Epoxy
2,2′-Ethylenebis(nitrilomethylidene)diphenol
Copper Acetate
1-methoxy-2-propanol

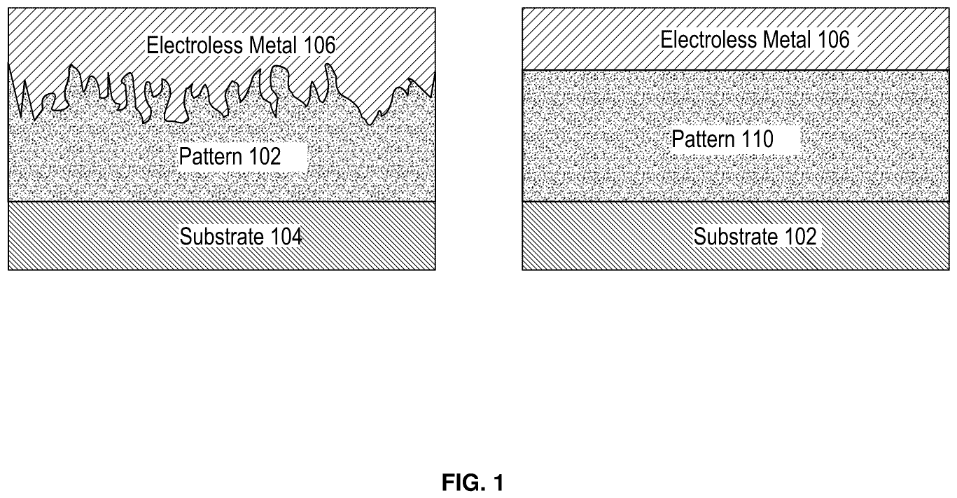

FIG. 1 shows illustrations of cross-sections of patterns made with inks with varying degrees of hydrophilicity according to embodiments of the present disclosure.

Referring to FIG. 1, a first pattern 102 may be formed on a substrate 104 using an ink with a degree of hydrophilicity. The pattern 102 defines an electroless metal 106 based on the pattern 102. A second pattern 110 on the substrate 110 may be formed using an ink with a different degree of hydrophilicity, and may define the electroless metal 106 accordingly. The interface between the polymer portions of the ink and the plated metal may be affected by the degree of hydrophilicity. Tuning the hydrophilicity such that metal deposition occurs within the interior of the ink layer but without reaching the substrate layer is preferred.

A technique for making a conductive pattern may include: depositing a first pattern on a substrate using a metal particle-free precursor ink, wherein the ink may include at least some of monomers, oligomers, or polymers; reducible metal ions or metal complexes; a photoinitiator; a reducing agent; and a chelating agent or ligand; curing the first pattern, by at least partially solidifying the pattern; generating catalytic nanoparticles within the first pattern by reduction of at least a portion of the metal ions or metal complexes; and plating the first pattern using electroless chemistry to form a conductive pattern.

FIG. 2 is a flow chart for a method 200 for implementing the usage of metal particle-free precursor inks wherein catalytic particle generation step occurs separately from the ink curing step and preferably close in time to the plating step according to embodiments of the present disclosure.

Referring to FIG. 2, at block 202, a particle pattern precursor ink (e.g., particle free) may be selected. At block 204, the precursor pattern may be cured (e.g., resulting in minimal particles). In addition, at block 204a, the cured precursor pattern may be stored. At block 206, the method 200 may reduce the precursor to generate catalytic particles to activate a catalytic pattern. At block 208, the method 200 may including plating the catalytic pattern.

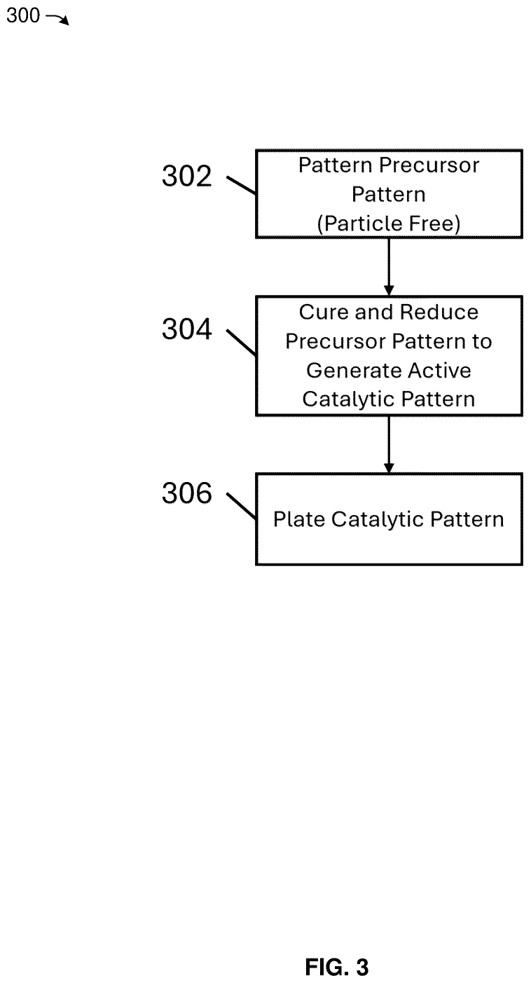

FIG. 3 is a flow chart for a method 300 of implementing the usage of metal particle-free catalytic precursor inks wherein the ink curing, and metal ion reduction occurs in one step according to embodiments of the present disclosure.

Referring to FIG. 3, at block 302, the precursor pattern (e.g., particle free) may be formed. At block 304, the method 300 may include curing and reducing the precursor pattern to generate an active catalytic pattern. At block 306, the method 300 may include plating the catalytic pattern.

It is understood that the above descriptions are for the purposes of illustration and are not meant to be limiting.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wireless communication device such as a cellular telephone, a smartphone, a tablet, a netbook, a wireless terminal, a laptop computer, a femtocell, a high data rate (HDR) subscriber station, an access point, a printer, a point of sale device, an access terminal, or other personal communication system (PCS) device. The device may be either mobile or stationary.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

The operations and processes described and shown above may be carried out or performed in any suitable order as desired in various implementations. Additionally, in certain implementations, at least a portion of the operations may be carried out in parallel. Furthermore, in certain implementations, less than or more than the operations described may be performed.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A method for making a conductive pattern comprising:
depositing a first pattern on a substrate using a metal particle-free precursor ink, wherein the ink comprises:
monomers, oligomers, or polymers;
reducible metal ions or metal complexes;
a photoinitiator;
a reducing agent; and
a chelating agent or ligand;
curing the first pattern, by at least partially solidifying the pattern;
generating catalytic nanoparticles within the first pattern by reduction of at least a portion of the metal ions or metal complexes; and
plating the first pattern using electroless chemistry to form a conductive pattern.

2. The method of claim 1, wherein a plating catalyst precursor of the plating comprises at least one of a silver (Ag) salt, a copper (Cu) salt, a palladium (Pd) salt, a nickel (Ni) salt, a gold (Au) salt, a platinum (Pt) salt or any other source of metal ions suitable for use as an electroplating catalyst.

3. The method of claim 1, wherein additives are used to modify a property of the ink.

4. The method of claim 3, wherein the property comprises hydrophilicity, viscosity, or photoinitiator sensitivity.

5. The method of claim 1, wherein the chelating agent or ligand comprises a group selected from one of the following: an aldimine, a pyridine, a pyrazine, a carboxylic acid, an alkyl amine, an alcohol amine, ammonia, or an aldehyde.

6. The method of claim 1, wherein the monomers, oligomers, and polymers comprise acrylates and are mixed with a photoinitiator to initiate the polymerization or crosslinking of the monomers and oligomers.

7. The method of claim 1, wherein the reduction of a majority of the metal ions or metal complexes to metal nanoparticles occurs simultaneously with the curing.

8. The method of claim 1, wherein the reduction of the metal ions or metal complexes to metal nanoparticles does not occur during the curing, and wherein a majority of the reduction is triggered at a later time after the curing by application of thermal or light energy.

9. The method of claim 1, wherein the reductant is selected based on a minimized reduction at an operating temperature and requested conditions.

10. The method of claim 1, wherein the reductant is selected from one of the following: an alcohol, an aldimine, an amide, an aldoxime, an aldehyde, a hydrazine, a hypophosphite, an oxime, or combinations thereof.

11. A method for making a conductive pattern comprising:
depositing a first pattern on a substrate using a metal particle-free precursor ink, wherein the ink comprises:
monomers, oligomers, or polymers;
reducible metal ions or metal complexes;
a thermal initiator;
a reducing agent; and
a chelating agent or ligand;
curing the first pattern, by at least partially solidifying the pattern;
generating catalytic nanoparticles within the first pattern by reduction of the metal ions or metal complexes; and
plating the first pattern using electroless chemistry to form a conductive pattern.

12. The method of claim 11, wherein the monomers, oligomers, and polymers comprise at least one of the following: epoxies, urethanes, polyesters, or vinyl polymers.

13. The method of claim 11, wherein additives are used to modify a property of the ink, and wherein the property comprises a hydrophilicity, viscosity, photoinitiator sensitivity, or a curing rate.

14. The method of claim 11, wherein the chelating agent or ligand comprises a group selected from one of the following: an aldimine, a pyridine, a pyrazine, a carboxylic acid, an alkyl amine, an alcohol amine, ammonia, or an aldehyde.

15. The method of claim 11, wherein the monomers, oligomers, and polymers comprise acrylates and are mixed with a photoinitiator to initiate the polymerization or crosslinking of the monomers and oligomers.

16. The method of claim 11, wherein the reduction of a majority of the metal ions or metal complexes to metal nanoparticles occurs simultaneously with the curing.

17. The method of claim 11, wherein the reduction of the metal ions or metal complexes to metal nanoparticles does not occur during the curing, and wherein a majority of the reduction is triggered at a later time after the curing by application of thermal or light energy.

18. The method of claim 11, wherein the reductant is selected based on a minimized reduction at an operating temperature and requested conditions.

19. The method of claim 11, wherein the reductant is selected from one of the following: an alcohol, an aldimine, an amide, an aldoxime, an aldehyde, a hydrazine, a hypophosphite, an oxime, or combinations thereof.

20. A method for making a conductive pattern comprising:
depositing a first pattern on a substrate using a metal particle-free precursor ink, wherein the ink comprises:
monomers, oligomers, or polymers;
reducible metal ions or metal complexes;
a chelating agent or ligand; and
solvent;
curing the first pattern, by at least partially solidifying the pattern by evaporation of solvent;
generating catalytic nanoparticles within the first pattern by reduction of the metal ions or metal complexes; and
plating the first pattern using electroless chemistry to form a conductive pattern.
